(19) United States
(12) Patent Application Publication
(10) Pub. No.: US 2021/0256218 A1
(43) Pub. Date: Aug. 19, 2021

(54) INTEGRATED REQUIREMENTS DEVELOPMENT AND AUTOMATED GAP ANALYSIS FOR HARDWARE TESTING USING NATURAL LANGUAGE PROCESSING

(71) Applicant: Raytheon Company, Waltham, MA (US)

(72) Inventors: Nicholas W. Barrett, Oro Valley, AZ (US); Steven J. Elder, Tucson, AZ (US); Abraham Wu, Tucson, AZ (US)

(21) Appl. No.: 16/793,913

(22) Filed: Feb. 18, 2020

(51) Int. Cl. G06F 40/30; G06N 20/00; G01R 31/28

(52) U.S. Cl. CPC G06F 40/30; G01R 31/2832; G06N 20/00

(57) ABSTRACT

A method includes analyzing testing capabilities information associated with multiple pieces of testing equipment by performing a first natural language processing (NLP) operation to identify capabilities of the testing equipment during hardware testing. The method also includes analyzing testing requirements information associated with a design of a hardware device by performing a second NLP operation to identify characteristics of testing requirements to be used to test the hardware device. The method further includes identifying at least one gap between the testing requirements to be used to test the hardware device and the capabilities of the testing equipment. In addition, the method includes generating a graphical user interface identifying the at least one gap.

### TECHNICAL FIELD

This disclosure is generally directed to computing systems. More specifically, this disclosure is directed to integrated requirements development and automated gap analysis for hardware testing using natural language processing.

### BACKGROUND

Designing hardware products often involves various personnel performing a number of different tasks. For example, systems engineers are often involved in the creation and maintenance of physical designs for hardware products, and test architects are often involved in the creation of testing plans to be used for testing the products during or after manufacturing or assembly. These hardware products can span a wide range of product types, such as electronic devices, computing devices, vehicles or other automotive products, and defense-related products.

### SUMMARY

This disclosure relates to integrated requirements development and automated gap analysis for hardware testing using natural language processing (NLP).

In a first embodiment, a method includes analyzing testing capabilities information associated with multiple pieces of testing equipment by performing a first NLP operation to identify capabilities of the testing equipment during hardware testing. The method also includes analyzing testing requirements information associated with a design of a hardware device by performing a second NLP operation to identify characteristics of testing requirements to be used to test the hardware device. The method further includes identifying at least one gap between the testing requirements to be used to test the hardware device and the capabilities of the testing equipment. In addition, the method includes generating a graphical user interface identifying the at least one gap.

In a second embodiment, an apparatus includes at least one memory configured to store testing capabilities information associated with multiple pieces of testing equipment and testing requirements information associated with a design of a hardware device. The apparatus also includes at least one processor configured to analyze the testing capabilities information by performing a first NLP operation to identify capabilities of the testing equipment during hardware testing. The at least one processor is also configured to analyze the testing requirements information by performing a second NLP operation to identify characteristics of testing requirements to be used to test the hardware device. The at least one processor is further configured to identify at least one gap between the testing requirements to be used to test the hardware device and the capabilities of the testing equipment and to generate a graphical user interface identifying the at least one gap.

In a third embodiment, a non-transitory computer readable medium contains instructions that when executed cause at least one processor to analyze testing capabilities information associated with multiple pieces of testing equipment by performing a first NLP operation to identify capabilities of the testing equipment during hardware testing. The medium also contains instructions that when executed cause the at least one processor to analyze testing requirements information associated with a design of a hardware device by performing a second NLP operation to identify characteristics of testing requirements to be used to test the hardware device. The medium further contains instructions that when executed cause the at least one processor to identify at least one gap between the testing requirements to be used to test the hardware device and the capabilities of the testing equipment. In addition, the medium contains instructions that when executed cause the at least one processor to generate a graphical user interface identifying the at least one gap.

Other technical features may be readily apparent to one skilled in the art from the following figures, descriptions, and claims.

### BRIEF DESCRIPTION OF THE DRAWINGS

For a more complete understanding of this disclosure, reference is now made to the following description, taken in conjunction with the accompanying drawings, in which:

FIG. 1 illustrates an example system supporting integrated requirements development and automated gap analysis for hardware testing using natural language processing according to this disclosure;

FIG. 2 illustrates an example device supporting integrated requirements development and automated gap analysis for hardware testing using natural language processing according to this disclosure;

FIG. 3 illustrates an example functional architecture supporting integrated requirements development and automated gap analysis for hardware testing using natural language processing according to this disclosure;

FIG. 4 illustrates example testing requirements for a hardware product used to support integrated requirements development and automated gap analysis according to this disclosure;

FIG. 5 illustrates example testing capabilities for testing equipment used to support integrated requirements development and automated gap analysis according to this disclosure;

FIGS. 6A and 6B illustrate example graphical user interfaces supporting integrated requirements development and automated gap analysis for hardware testing using natural language processing according to this disclosure; and

FIG. 7 illustrates an example method for integrated requirements development and automated gap analysis for hardware testing using natural language processing according to this disclosure.

### DETAILED DESCRIPTION

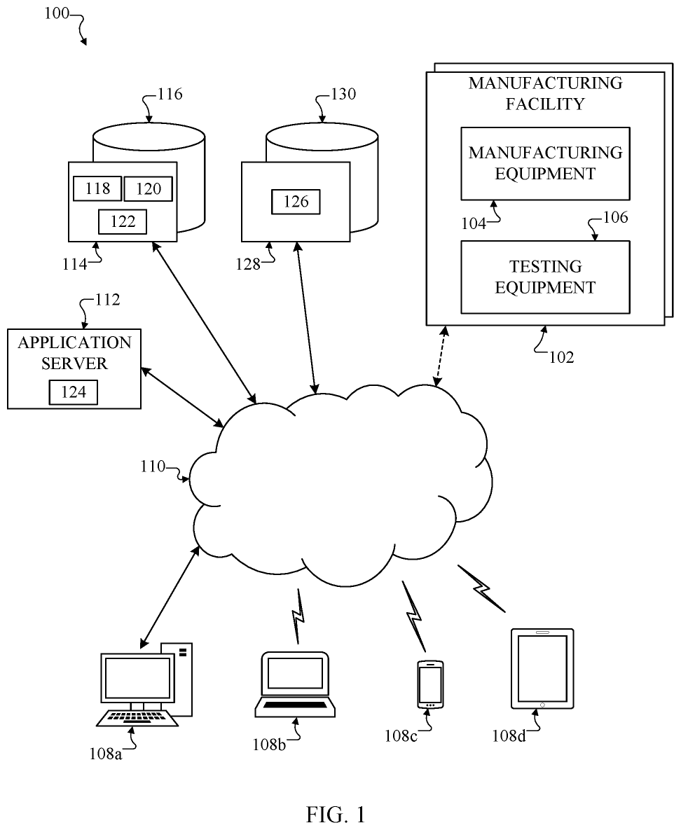

FIGS. 1 through 7, described below, and the various embodiments used to describe the principles of the present invention in this patent document are by way of illustration only and should not be construed in any way to limit the scope of the invention. Those skilled in the art will understand that the principles of the present invention may be implemented in any type of suitably arranged device or system.

As noted above, designing a hardware product often involves various personnel performing a number of different tasks. For example, systems engineers are often involved in the creation and maintenance of a physical design for a hardware product, and this process often includes the creation of high-level hardware requirements for the hardware product. Also, test architects are often involved in the creation of a testing plan to be used for testing the hardware product during or after manufacturing or assembly, and this process often includes the creation of high-level testing requirements for the hardware product. These hardware products can span a wide range of product types, such as electronic devices, computing devices, vehicles or other automotive products, and defense-related products. Often times, a design process that involves the creation of high-level hardware requirements and high-level testing requirements is referred to as a “requirements-driven” development process.

Unfortunately, it is not uncommon for hardware and testing requirements for hardware products to be created and then for personnel to learn that desired testing of the hardware products cannot be performed. For example, system engineers may work to create hardware requirements for a hardware design while test architects work to create testing requirements for the hardware design, but the personnel may learn later that testing equipment available at a manufacturing facility is unable to perform the desired testing of the hardware. When this occurs, additional testing equipment may need to be purchased (which can be expensive), or the hardware requirements and/or testing requirements may need to be revised (which can cause delays). This may be problematic if, for instance, some of the hardware requirements or testing requirements cannot be changed. This problem can be particularly difficult to solve when hardware products can be manufactured using different manufacturing facilities, each of which may have its own unique set of testing equipment available at that facility.

This disclosure provides various techniques for integrated requirements development and automated gap analysis for hardware testing, which are performed using natural language processing. As described in more detail below, an automated gap analysis is performed using testing requirements and testing capabilities. The testing requirements generally define the overall desired testing to be performed on a hardware product and are typically developed during a design process for the hardware product. For example, the testing requirements may define the conditions to occur during one or more hardware tests, the characteristics to be measured during the hardware test(s), and the values to be considered acceptable or unacceptable for the measured characteristics. The testing requirements used here may be based at least partially on hardware requirements that are developed during the design process for the hardware product, since the tests to be performed depend (at least in part) on the actual design of the hardware product.

The testing capabilities define the capabilities of testing equipment available for use in testing hardware products, such as at one or more manufacturing facilities or other facilities. For example, the testing capabilities may define the types of input signals that can be injected into hardware being tested by test equipment, the types of output signals that can be measured from the hardware being tested by the test equipment, and ranges of values and units of measure for the input and output signals. The testing capabilities of the test equipment are typically not tailored to individual hardware product designs, since the testing equipment is often designed for use across a range of inputs and outputs. In some cases, the testing equipment that is available for use is referred to as common industry testing equipment, meaning the testing equipment and its features may be generally common across various manufacturers. However, in other cases, the testing equipment that is available for use may be custom, proprietary, or otherwise unique, possibly even across different manufacturing facilities of the same manufacturer.

Natural language processing is applied to the testing requirements and the testing capabilities in order to learn both (i) the desired testing for a hardware design and (ii) the available testing that can be performed on the hardware design, and an ontology-driven analysis or other analysis is performed to identify gaps between the desired testing and the actual testing capabilities. The gaps identify where the current testing capabilities of the testing equipment are inadequate to meet the current testing requirements, so the current testing requirements cannot be used to test the current hardware design. In other words, each gap identifies where the desired testing of the hardware design may not be possible or feasible given the current or expected capabilities of the testing equipment. The analysis can also compare and contrast the current testing requirements to historical testing requirements in order to determine whether the current testing requirements are possible in light of previously-validated testing requirements. If gaps are detected during the analysis, a graphical user interface may be generated that identify the gaps.

In this way, systems engineers, test architects, or other personnel may learn early in the design process whether a hardware product being designed can be adequately tested using available testing equipment. If not, the personnel can work together to respond accordingly, such as by redesigning the hardware product or the desired tests, adding test capabilities to the testing equipment, or performing other actions. Among other things, this can help to reduce development times and improve design accuracy. Moreover, this can occur at an important location in a product development process to enable concurrent engineering of the hardware requirements (for the hardware design) and the testing requirements (for product testability). Again, delays associated with the overall development process can be reduced, possibly quite significantly. As a particular example, some studies have shown that around 80% of the development costs for a hardware product are associated with the product's requirements development phase, which includes development of hardware requirements and testing requirements. The approaches described here provide improved insight into the testability (and therefore the “produceability”) of a hardware product during the requirements development phase, helping to shorten the overall engineering development process (which can provide great commercial value). Further, the described techniques can provide for more consistent analysis of testing requirements relative to testing capabilities, since subjective decision-making can be significantly reduced or eliminated in the analysis. In addition, any gaps identified using the described techniques can be used to inform appropriate personnel about the costs and complexities of the testing equipment needed by a current hardware design or testing plan. Thus, the personnel can decide whether the costs and complexities are worthwhile or whether revisions to hardware or testing requirements should be made.

FIG. 1 illustrates an example system 100 supporting integrated requirements development and automated gap analysis for hardware testing using natural language processing according to this disclosure. As shown in FIG. 1, the system 100 includes, is used in conjunction with, or is otherwise associated with at least one manufacturing facility 102. Each manufacturing facility 102 can be used to manufacture, assemble, or otherwise produce hardware products, such as electronic devices, computers, vehicles, defense-related products, or other hardware products. In this example, each manufacturing facility 102 includes various manufacturing equipment 104 and various testing equipment 106. The manufacturing equipment 104 generally represents the components used to manufacture, assemble, or otherwise produce hardware products, such as robotic assembly components. The testing equipment 106 generally represents the components used to test the hardware products being produced, such as during or after manufacture or assembly. In some cases, the testing equipment 106 may include common industry testing equipment, common factory testing platforms (CFTPs), or Composable Testing Modules (CTMs). Note, however, that any suitable manufacturing and testing equipment may be used here.

In general, the system 100 may be associated with a single facility 102 or with multiple facilities 102, and each facility 102 may include any suitable manufacturing equipment 104 and any suitable testing equipment 106. Different facilities 102 (if present) may include common or different manufacturing equipment 104 and common or different testing equipment 106. Each facility 102 may be used to produce any suitable hardware products, and different facilities 102 (if present) may produce common or different hardware products. Note, however, that each individual facility 102 need not include both manufacturing equipment 104 and testing equipment 106. Thus, for instance, one or more facilities 102 may include manufacturing equipment 104, and one or more other facilities 102 may include testing equipment 106. This disclosure is not limited to use with any particular type(s) or arrangement(s) of equipment 104, 106 in one or more facilities 102.

The system 100 also includes multiple user devices 108a-108d, at least one network 110, at least one application server 112, and at least one database server 114 associated with at least one database 116. Note, however, that other combinations and arrangements of components may also be used here.

In this example, each user device 108a-108d is coupled to or communicates over the network 110. Communications between each user device 108a-108d and a network 110 may occur in any suitable manner, such as via a wired or wireless connection. Each user device 108a-108d represents any suitable device or system used by at least one user to provide information to the application server 112 or database server 114 or to receive information from the application server 112 or database server 114. Any suitable number(s) and type(s) of user devices 108a-108d may be used in the system 100. In this particular example, the user device 108a represents a desktop computer, the user device 108b represents a laptop computer, the user device 108c represents a smartphone, and the user device 108d represents a tablet computer. However, any other or additional types of user devices may be used in the system 100. Each user device 108a-108d includes any suitable structure configured to transmit and/or receive information.

The network 110 facilitates communication between various components of the system 100. For example, the network 110 may communicate Internet Protocol (IP) packets, frame relay frames, Asynchronous Transfer Mode (ATM) cells, or other suitable information between network addresses. The network 110 may include one or more local area networks (LANs), metropolitan area networks (MANs), wide area networks (WANs), all or a portion of a global network such as the Internet, or any other communication system or systems at one or more locations. The network 110 may also operate according to any appropriate communication protocol or protocols. In this example, the network 110 may optionally be coupled to each facility 102, such as to receive information from manufacturing equipment 104 or testing equipment 106. However, this is optional since various components of the system 100 may operate without having communication capabilities with the facility or facilities 102.

The application server 112 is coupled to the network 110 and is coupled to or otherwise communicates with the database server 114. The application server 112 executes one or more applications to support various functions in the system 100, and the database server 114 and database 116 store various information used to support the execution of the one or more applications. For example, the database server 114 and database 116 may be used to store hardware requirements information 118, testing requirements information 120, and testing capabilities information 122.

The hardware requirements information 118 generally represents hardware requirements or other hardware design information associated with one or more hardware products manufactured or to be manufactured. In some cases, the hardware requirements information 118 may be provided at least in part by one or more users of the devices 108a-108d and can define the high-level hardware design for a hardware product. Initial hardware requirements information 118 for a product can be generated during a design process for the hardware product involving one or more users, and the hardware requirements information 118 for the hardware product may be updated over time.

The testing requirements information 120 generally represents information associated with a testing plan for at least one hardware product. For example, the testing requirements information 120 may define the conditions to occur during one or more hardware tests, the characteristics to be measured during the hardware test(s), and the values to be considered acceptable or unacceptable for the measured characteristics. Ideally, the conditions, measured characteristics, and acceptable/unacceptable determinations are within the capabilities of the testing equipment 106 in one or more facilities 102, although as noted above this is not always the case. The testing requirements information 120 may be based at least partially on the hardware requirements information 118, since the testing to be performed on a hardware product depends at least in part on the design of the hardware product.

The testing requirements information 120 here can take various forms, such as a test requirements document, a master test list, or a test architecture plan. In some cases, the testing requirements information 120 may be provided at least in part by one or more users of the devices 108a-108d. The testing requirements information 120 may be created independently or may be based on other information, such as when the testing requirements information 120 relates to a hardware product being designed for a customer (in which case the customer might provide at least some testing requirements for the hardware product). The testing requirements information 120 for a hardware product may be generated in an overlapping manner with the hardware requirements information 118 for the hardware product, thereby enabling concurrent engineering and integrated requirements development. This may also enable higher-level functions, such as model-based engineering.

The testing capabilities information 122 generally represents information defining the capabilities of the testing equipment 106 that is or will be available for use in testing hardware products, such as at one or more facilities 102. For example, the testing capabilities information 122 may define the types of input signals that can be injected into hardware being tested by the test equipment 106, the types of output signals that can be measured from the hardware being tested by the test equipment 106, and ranges of values and units of measure for the input and output signals. The testing capabilities information 122 here may relate to common industry testing equipment 106, custom/proprietary/unique testing equipment 106, or other testing equipment 106 that is available or that will become available for use in testing hardware products.

The testing capabilities information 122 here can take various forms, such as a test capabilities document. In some cases, the testing capabilities information 122 may be provided at least in part by one or more users of the devices 108a-108d. The testing capabilities information 122 may be created independently or may be based on other information, such as when the testing capabilities information 122 is based on documentation associated with particular pieces of testing equipment 106. The testing capabilities information 122 may be obtained at any suitable time(s), such as before or during the design process in which the hardware requirements information 118 and the testing requirements information 120 are generated.

The application server 112 can retrieve various information from the database 116 via the database server 114 and process the information to support automated gap analysis. For example, the application server 112 may include or have access to one or more natural language processing (NLP) models 124, which represent machine learning models that have been trained to perform one or more natural language processing tasks. In this example, the one or more NLP models 124 can be used to analyze the testing requirements information 120 and the testing capabilities information 122. This allows the testing requirements information 120 to be broken down into various defining characteristics associated with hardware tests to be performed. This also allows the testing capabilities information 122 to be broken down into various capability characteristics associated with the testing equipment 106. In some cases, the capability characteristics of the testing capabilities information 122 are used to define at least one ontology 126, which is used to represent the various capabilities of the testing equipment 106 that might be used to test hardware products.

The application server 112 may compare the defining characteristics associated with the testing requirements information 120 to the capability characteristics associated with the testing equipment 106, which may be contained in the at least one ontology 126. The application server 112 can then identify which (if any) of the characteristics associated with the testing requirements information 120 cannot be satisfied using the available testing equipment 106, which as noted above are referred to as “gaps.” One or more gaps indicate that one or more characteristics associated with the testing requirements information 120 cannot be satisfied using the available testing equipment 106, meaning a hardware product designed in accordance with the hardware requirements information 118 might not be testable based on the testing requirements information 120 for the hardware product. One or more graphical user interfaces or other mechanisms may be used to provide information about any identified gaps to one or more users, which allows the user(s) to make changes to the hardware requirements information 118 and/or the testing requirements information 120 in order to overcome the deficiencies in the testing equipment 106. Additional details regarding example operations of the application server 112 are provided below.

Note that the use of the at least one ontology 126 is optional here, since the application server 112 may compare the testing requirements information 120 to the testing capabilities information 122 in other ways. For instance, the testing capabilities information 122 of the testing equipment 106 may be summarized or otherwise processed in other ways to enable suitable comparisons against the testing requirements information 120. Also note that the order of operations discussed above with respect to the application server 112 can vary as needed or desired. For example, the application server 112 may obtain testing capabilities information 122 and possibly generate one or more ontologies 126 at any suitable time(s), such as before or during a design process associated with a specific hardware product. As a particular example, the testing capabilities information 122 or related information (such as the one or more ontologies 126) may be stored and used during any subsequent design processes for hardware products. The testing capabilities information 122 or one or more ontologies 126 need not be updated or replaced as long as the testing capabilities of the testing equipment 106 do not change. If the testing capabilities of at least one piece of the testing equipment 106 changes, the testing capabilities information 122 or one or more ontologies 126 can be updated or replaced based on the updated testing capabilities.

Each NLP model 124 includes any suitable machine learning model that has been trained to recognize natural language and perform an NLP task. In some embodiments, the application server 112 may include multiple NLP models 124, where each model 124 is trained to perform a different NLP task. As a particular example, one NLP model 124 may be trained to extract certain information (such as defining characteristics) of one or more hardware tests from the testing requirements information 120, and another NLP model 124 may be trained to extract certain information (such as capability characteristics) of one or more pieces of testing equipment 106 from the testing capabilities information 122. Since the characteristics of hardware tests and the characteristics of testing equipment can be expressed in different ways in the testing requirements information 120 and the testing capabilities information 122, different NLP models 124 may be used to identify and extract these characteristics. However, this need not be the case, and a single NLP model 124 may be trained to extract the characteristics of both the hardware tests and the testing equipment 106.

Each NLP model 124 is typically trained by applying a machine learning algorithm to one or more sets of training data, where the model 124 is trained by adjusting weights or other parameters of the model 124 so that the model 124 correctly analyzes the training data. For example, training data may include known characteristics of known hardware tests, and a model 124 can be trained so that the model 124 properly analyzes the known characteristics of the known hardware tests. As particular examples, the training data may include known characteristics of different analog voltage tests, analog current tests, and digital input tests, and a machine learning algorithm can train a model 124 to recognize the different characteristics. Similarly, training data may include known capabilities of known testing equipment, and a model 124 can be trained so that the model 124 properly analyzes the known characteristics of the known testing equipment. As particular examples, the training data may include known capabilities of testing equipment in terms of voltages, currents, or other inputs that can be generated and voltages, currents, or other outputs that can be measured by testing equipment, and a machine learning algorithm can train a model 124 to recognize the different capabilities. Any suitable machine learning algorithm may be used to produce each of the one or more NLP models 124. Various machine learning algorithms are known in the art, and many additional machine learning algorithms are sure to be developed in the future.

Each ontology 126 includes any suitable information defining the testing capabilities of the testing equipment 106 in or associated with the system 100. In computer and information sciences, an “ontology” generally refers to a formal representation of abstract concepts, concrete instances of those concepts, and relationships between the concepts and instances. In the context of FIG. 1, the at least one ontology 126 can be used to store information related to the types of hardware tests that are supported by the testing equipment 106, such as information related to the tests' inputs and outputs. In some cases, the at least one ontology 126 can also incorporate knowledge about prior testing requirements that are known to have been validated or satisfied by the capabilities of the testing equipment 106.

In this example, the one or more ontologies 126 are managed by a “triple store” server 128, which can store the ontologies 126 in a “triple store” database 130. The database 130 may store and facilitate retrieval or use of the ontologies 126, and the server 128 may support higher-level functions associated with the at least one ontology 126, such as automated reasoning where information in an ontology 126 is compared to various rules to ensure compliance with the rules or where information in an ontology 126 is used to derive additional information about the capabilities of the testing equipment 106 via inferencing.

Note that the phrase “hardware testing” in this document refers to any testing that involves a hardware product. Hardware testing may include testing of individual hardware components in a hardware product, groups of hardware components in a hardware product, and an entire hardware product itself. Hardware testing may also or alternatively include testing of software or firmware stored on a hardware product. In general, hardware testing can encompass a large number of manufacturing, quality assurance, or other testing that involves a hardware product.

Additional details regarding the functionality provided by the application server 112 are provided below. It should be noted that while this functionality is described as being performed by the application server 112 in the system 100, the same or similar functionality may be provided by any other suitable devices, and the devices need not operate in the system 100. Also, it should be noted that while often described as being used in a stand-alone manner to identify testing gaps, this functionality can be incorporated into a larger system, such as when incorporated into a software package that is designed to help users generate and analyze hardware requirements and/or testing requirements.

Although FIG. 1 illustrates one example of a system 100 supporting integrated requirements development and automated gap analysis for hardware testing using natural language processing, various changes may be made to FIG. 1. For example, the system 100 may include any number of facilities 102, manufacturing equipment 104, testing equipment 106, user devices 108a-108d, networks 110, servers 112, 114, 128, and databases 116, 130. Also, these components may be located in any suitable locations and might be distributed over a large area. Further, various components shown in FIG. 1 may be combined, further subdivided, replicated, omitted, or placed in any other suitable arrangement and additional components may be added according to particular needs. As a particular example, the databases 116, 130 may be combined, and the functionality of the servers 114, 128 may be combined. In addition, while FIG. 1 illustrates one example operational environment in which automated gap analysis for hardware testing may be used to support functions such as integrated requirements development, this functionality may be used in any other suitable system.

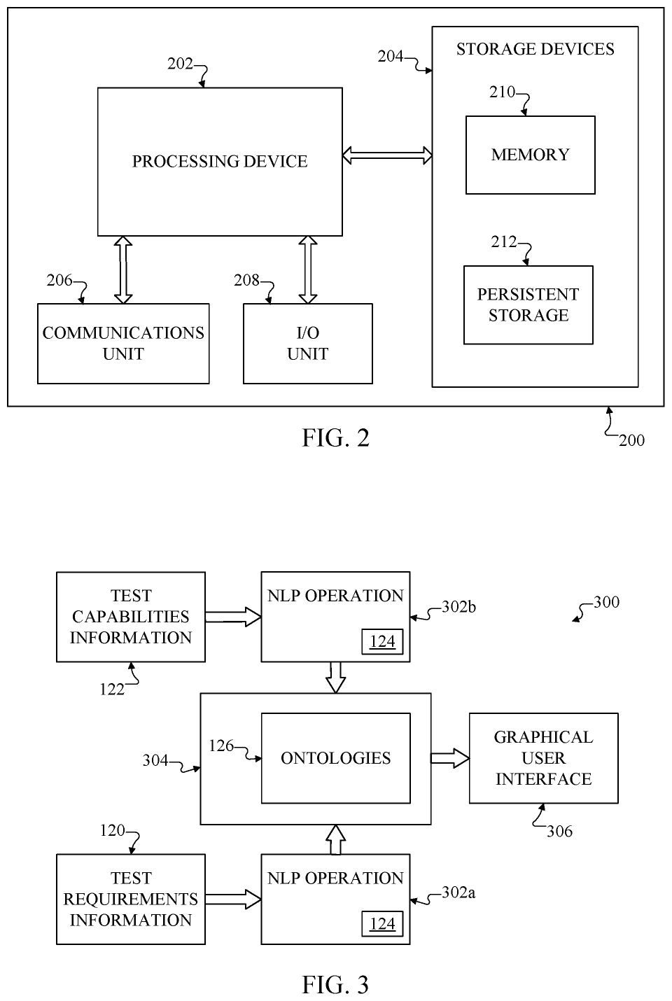

FIG. 2 illustrates an example device 200 supporting integrated requirements development and automated gap analysis for hardware testing using natural language processing according to this disclosure. One or more instances of the device 200 may, for example, be used to at least partially implement the functionality of the application server 112 of FIG. 1. However, the functionality of the application server 112 may be implemented in any other suitable manner. In some embodiments, the device 200 shown in FIG. 2 may form at least part of a user device 108a-108d, application server 112, or database server 114 in FIG. 1. However, each of these components may be implemented in any other suitable manner.

As shown in FIG. 2, the device 200 denotes a computing device or system that includes at least one processing device 202, at least one storage device 204, at least one communications unit 206, and at least one input/output (I/O) unit 208. The processing device 202 may execute instructions that can be loaded into a memory 210. The processing device 202 includes any suitable number(s) and type(s) of processors or other processing devices in any suitable arrangement. Example types of processing devices 202 include one or more microprocessors, microcontrollers, digital signal processors (DSPs), application specific integrated circuits (ASICs), field programmable gate arrays (FPGAs), or discrete circuitry.

The memory 210 and a persistent storage 212 are examples of storage devices 204, which represent any structure(s) capable of storing and facilitating retrieval of information (such as data, program code, and/or other suitable information on a temporary or permanent basis). The memory 210 may represent a random access memory or any other suitable volatile or non-volatile storage device(s). The persistent storage 212 may contain one or more components or devices supporting longer-term storage of data, such as a read only memory, hard drive, Flash memory, or optical disc.

The communications unit 206 supports communications with other systems or devices. For example, the communications unit 206 can include a network interface card or a wireless transceiver facilitating communications over a wired or wireless network. The communications unit 206 may support communications through any suitable physical or wireless communication link(s). As a particular example, the communications unit 206 may support communication over the network(s) 110 of FIG. 1.

The I/O unit 208 allows for input and output of data. For example, the I/O unit 208 may provide a connection for user input through a keyboard, mouse, keypad, touchscreen, or other suitable input device. The I/O unit 208 may also send output to a display, printer, or other suitable output device. Note, however, that the I/O unit 208 may be omitted if the device 200 does not require local I/O, such as when the device 200 represents a server or other device that can be accessed remotely.

In some embodiments, the instructions executed by the processing device 202 may include instructions that perform natural language processing of testing requirements information 120 and testing capabilities information 122 using one or more NLP models 124. The instructions executed by the processing device 202 may also include instructions that create one or more ontologies 126 using the NLP processing results of the testing capabilities information 122. The instructions executed by the processing device 202 may further include instructions that compare the NLP processing results of the testing requirements information 120 to the one or more ontologies 126 in order to identify any gaps between desired testing of a hardware product and testing capabilities of the testing equipment 106. In addition, the instructions executed by the processing device 202 may include instructions that generate and present one or more graphical user interfaces identifying any gaps.

Although FIG. 2 illustrates one example of a device 200 supporting integrated requirements development and automated gap analysis for hardware testing using natural language processing, various changes may be made to FIG. 2. For example, computing and communication devices and systems come in a wide variety of configurations, and FIG. 2 does not limit this disclosure to any particular computing or communication device or system.

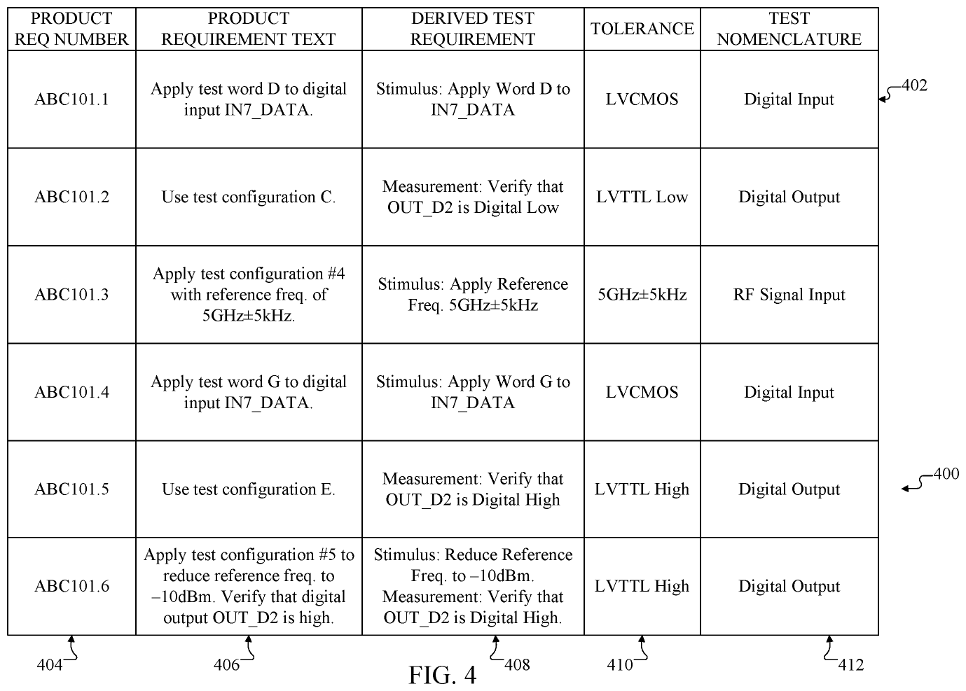

FIG. 3 illustrates an example functional architecture 300 supporting integrated requirements development and automated gap analysis for hardware testing using natural language processing according to this disclosure. For ease of explanation, the functional architecture 300 shown in FIG. 3 may be described as being implemented or supported using one or more components in the system 100 of FIG. 1, at least one of which may be implemented using at least one instance of the device 200 of FIG. 2. However, the functional architecture 300 shown in FIG. 3 may be implemented or supported by any suitable device(s) and in any suitable system(s).

As shown in FIG. 3, the functional architecture 300 receives the testing requirements information 120 and the testing capabilities information 122. The testing requirements information 120 is processed using a natural language processing operation 302a, which uses at least one NLP model 124 that is trained to extract desired information from the testing requirements information 120. Similarly, the testing capabilities information 122 is processed using a natural language processing operation 302b, which uses at least one NLP model 124 that is trained to extract desired information from the testing capabilities information 122. The natural language processing operations 302a-302b extract specific information from the testing requirements information 120 and the testing capabilities information 122. Examples of the specific information extracted by the natural language processing operations 302a-302b are provided below.

In some embodiments, the testing requirements information 120 can be imported into the functional architecture 300, such as in one or more testing requirements documents or in any other suitable format(s). The natural language processing operation 302a processes the testing requirements information 120 using at least one trained NLP model 124 to extract defining characteristics associated with hardware tests to be performed for a hardware product. In particular embodiments, the defining characteristics of the hardware tests include at least some of the following parameters for each testing requirement: category, I/O type, target value, acceptable upper/lower bounds, and unit of measure. The category of each testing requirement can identify whether the testing requirement involves a stimulus (related to an input to a hardware product) or a measurement (related to an output from a hardware product). The I/O type of each testing requirement can identify the type of the associated input or output, such as whether the associated input or output is an analog voltage input or output, an analog current input or output, a digital input, or a digital output. The target value of each testing requirement can identify the ideal or desired value for an input or output, and the acceptable upper/lower bounds of each testing requirement can identify the acceptable range of values for an input or output. The unit of measure for each testing requirement can identify the units in which the associated target value and the associated acceptable upper/lower bounds are measured. Any of these or other or additional types of parameters of the testing requirements can be extracted from the testing requirements information 120 by the natural language processing operation 302a using the appropriately-trained NLP model(s) 124.

In some embodiments, the testing capabilities information 122 can be imported into the functional architecture 300, such as in one or more testing capabilities documents or in any other suitable format(s). The natural language processing operation 302b processes the testing capabilities information 122 using at least one trained NLP model 124 to extract capability characteristics associated with the testing equipment 106. In particular embodiments, the capability characteristics of the testing equipment 106 include at least some of the following parameters: category, type, upper/lower bounds, and unit of measure. Note that each piece of testing equipment 106 may have multiple sets of capability characteristics, such as when the testing equipment 106 is capable of generating different inputs for a hardware product and/or measuring different outputs from a hardware product. The category of each capability characteristic can identify whether the capability characteristic is associated with a stimulus or a measurement. The type of each capability characteristic can identify the type of the stimulus or measurement, such as whether the capability characteristic involves voltage, current, logic level, or other I/O type. The upper/lower bounds of each capability characteristic can identify the range of possible testing or measurement values for a stimulus or measurement, and the unit of measure for each capability characteristic can identify the units in which the associated upper/lower bounds are measured. Any of these or other or additional types of parameters of the testing requirements can be extracted from the testing capabilities information 122 by the natural language processing operation 302b using the appropriately-trained NLP model(s) 124.

An analysis operation 304 processes (among other things) the outputs of the natural language processing operations 302a-302b to identify gaps between desired testing of a hardware product being designed and actual testing capabilities of the testing equipment 106. For example, the analysis operation 304 can compare the extracted information from the natural language processing operation 302b with the extracted information from the natural language processing operation 302a to identify gaps between the desired testing (as defined by the testing requirements information 120) and the actual testing capabilities of the testing equipment 106 (as defined by the testing capabilities information 122). Effectively, the analysis operation 304 is identifying where the requirements for the desired testing of a hardware product cannot be satisfied based on the capabilities of the testing equipment 106.

In this example embodiment, the extracted information from the natural language processing operation 302b (possibly along with other information) can be used to generate one or more ontologies 126. The one or more ontologies 126 represent the knowledge about the capabilities of the testing equipment 106 that has been placed into a suitable form for storage and use, such as one or more knowledge graphs. The one or more ontologies 126 may optionally also include various additional information associated with the testing equipment 106 that might be useful, such as test block locations, related test capabilities, and test harness information. In this embodiment, the extracted information from the natural language processing operation 302a is compared to the one or more ontologies 126 by the analysis operation 304 in order to identify any gaps between the desired testing and the actual testing capabilities.

Note that there are various analysis techniques that may be used by the analysis operation 304 to compare the extracted information from the natural language processing operations 302a-302b. For example, the analysis operation 304 may perform various language and acronym analyses, along with the ontology analysis, to process the information from the natural language processing operations 302a-302b. In addition to the ontology analysis shown in FIG. 3 and described above, a language analysis can be used to associate equivalent extracted information from the natural language processing operations 302a-302b, and an acronym analysis may be used to identify acronyms and their meanings (and possibly to associate different acronyms or acronyms and related text) in the extracted information from the natural language processing operations 302a-302b. The analysis operation 304 can also compare and contrast the current testing requirements information 120 to historical testing requirements in order to determine whether the current testing requirements information 120 can be achieved in light of previously-validated testing requirements. In general, the analysis operation 304 can use a wide variety of techniques for identifying relevant information from the natural language processing operations 302a-302b and comparing that information, and this disclosure is not limited to any particular analysis technique.

The results from the analysis operation 304 include an identification of any gaps between the testing requirements information 120 and the testing capabilities information 122. As noted above, each gap identifies where the desired testing of a hardware product may not be possible or feasible given the current or expected capabilities of the testing equipment 106. This information may be used in any suitable manner. In this example, a graphical user interface operation 306 may generate one or more graphical user interfaces, which can be used to support various interactions with one or more users. For example, the graphical user interface operation 306 may generate a graphical user interface used to provide any identified gaps between the testing requirements information 120 and the testing capabilities information 122. Among other things, the graphical user interface operation 306 can provide real-time visualizations of identified gaps and related issues that affect the testing requirements information 120 based on the testing capabilities information 122.

In some embodiments, the graphical user interface operation 306 may also generate one or more graphical user interfaces used to receive inputs from one or more users, such as an identification of the testing requirements information 120 and the testing capabilities information 122 to be analyzed. In some cases, a graphical user interface may also be used to receive additional testing requirements or additional testing capabilities from one or more users, such as when a user can provide information identifying a new testing requirement to be used when testing a hardware product or information identifying a new testing capability of test equipment 106 (and this information can be provided to and used by the analysis operation 304 when identifying gaps). Thus, this information can be included in the testing requirements information 120 and/or the testing capabilities information 122. This may allow, for instance, at least one user to supplement or override a portion of the testing requirements information 120 and/or a portion of the testing capabilities information 122. As a particular example, this may allow a user to supplement the testing capabilities information 122 with a new capability, possibly to see whether actually adding that capability to the testing equipment 106 would reduce or eliminate any identified gaps.

The functional architecture 300 may be implemented in any suitable manner. For example, in some embodiments, the functional architecture 300 is implemented using software instructions that are executed by one or more processors of a computing device or other electronic device, such as when executed by the processing device(s) 202 of the device(s) 200 (which may represent the application server 112). As noted above, the functional architecture 300 may also be incorporated into a larger system, such as when incorporated into a software package that helps users generate and analyze hardware requirements and/or testing requirements.

Although FIG. 3 illustrates one example of a functional architecture 300 supporting integrated requirements development and automated gap analysis for hardware testing using natural language processing, various changes may be made to FIG. 3. For example, components can be added, omitted, combined, further subdivided, replicated, or placed in any other suitable configuration in the functional architecture 300 according to particular needs. Also, automated gap analysis for hardware testing may be used to support functions such as integrated requirements development in any other suitable functional architecture.

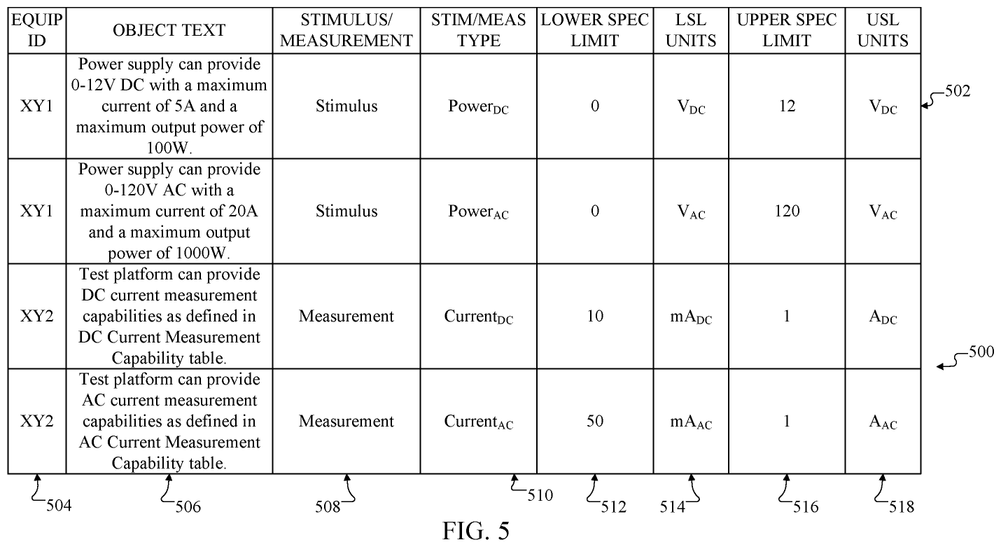

FIG. 4 illustrates example testing requirements 400 for a hardware product used to support integrated requirements development and automated gap analysis according to this disclosure. More specifically, the testing requirements 400 shown in FIG. 4 may represent information that is processed or generated by the natural language processing operation 302a. As shown in FIG. 4, the testing requirements 400 are arranged in a table, where each row 402 of the table is associated with at least part of a different testing requirement. Each testing requirement identified from the testing requirements information 120 may be associated with a single row 402 or multiple rows 402. Note that this organization is used merely for convenience, and the testing requirements 400 may be stored or expressed in any other suitable manner.

Each row 402 of the table includes a product requirement number 404, which identifies the testing requirement contained in or otherwise associated with that row 402. In this example, the product requirement numbers 404 in all illustrated rows 402 of the table contain the same prefix (“ABC101”), which may indicate that these rows 402 of the table relate to the same hardware product. However, different rows 402 of the table can be associated with any number of hardware products. Also, in this example, the product requirement numbers 404 are expressed using alphanumeric characters, although any other suitable identifiers may be used here.

Each row 402 of the table also includes product requirement text 406, which may represent text obtained from the testing requirements information 120. Each product requirement text 406 expresses at least part of a hardware test associated with a hardware product to be tested. For example, a product requirement text 406 can indicate an action to be performed, such as the application of at least one particular input (stimulus) to a hardware product and/or the capture of at least one particular output (measurement) from the hardware product. In some cases, each product requirement text 406 represents text from the testing requirements information 120 that has been identified (by the natural language processing operation 302a based on at least one NLP model 124) as containing at least one stimulus and/or at least one measurement.

Each row 402 of the table further includes a derived test requirement 408, which represents the product requirement text 406 as analyzed by the natural language processing operation 302a using the appropriate NLP model(s) 124. In this example, each derived test requirement 408 indicates whether the associated product requirement text 406 relates to a stimulus and/or a measurement. If related to a stimulus, the derived test requirement 408 identifies the value or range of values to be applied to an input of a hardware product. If related to a measurement, the derived test requirement 408 identifies the expected value or expected range of values to be measured from an output of a hardware product. The derived test requirements 408 can be produced by the natural language processing operation 302a analyzing the input texts (the product requirement texts 406) using one or more appropriately-trained NLP models 124.

Each row 402 of the table also includes a tolerance 410, which identifies a possible range of values for a stimulus and measurement (as well as the unit of measure for the range of values). In this example, some tolerances 410 are expressed by referring to predefined tolerances, such as tolerances associated with Low Voltage Complementary Metal Oxide Semiconductor (LVCMOS) devices or Low-Voltage Transistor-Transistor Logic (LVTTL) devices. However, this is simply for convenience, and tolerances 410 may be expressed in any other suitable manner. In addition, each row 402 of the table includes a test nomenclature 412, which identifies the I/O type of the testing requirement in the row 402. For instance, the test nomenclature 412 can identify whether a row 402 is associated with an analog or digital input or output, and the test nomenclature 412 can optionally identify the type of an analog input or output (such as voltage, current, radio frequency, etc.).

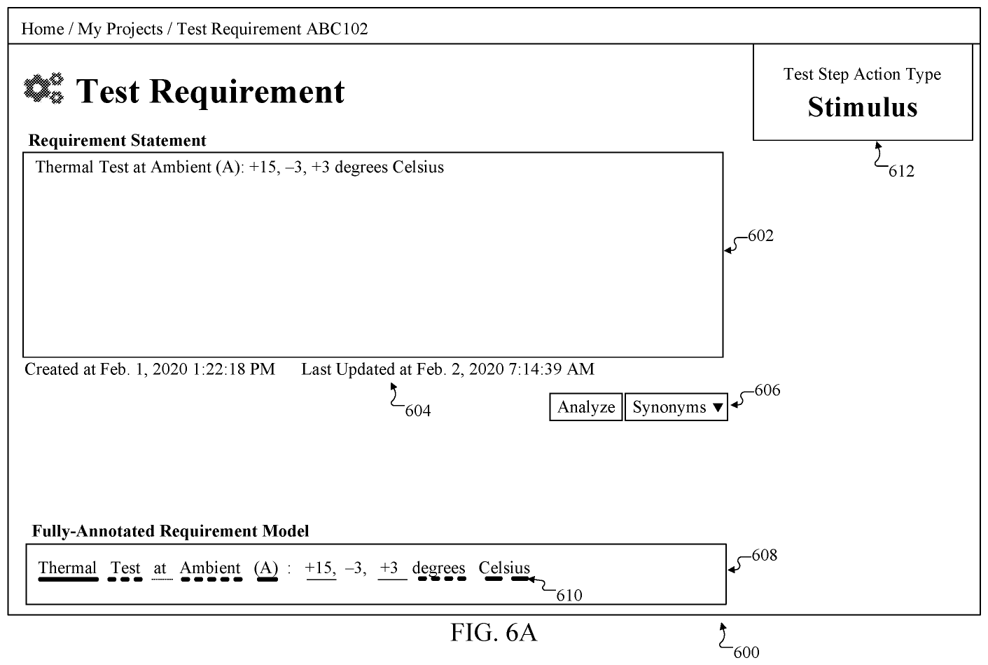

FIG. 5 illustrates example testing capabilities 500 for testing equipment used to support integrated requirements development and automated gap analysis according to this disclosure. More specifically, the testing capabilities 500 shown in FIG. 5 may represent information that is processed or generated by the natural language processing operation 302b. As shown in FIG. 5, the testing capabilities 500 are arranged in a table, where each row 502 of the table is associated with a different testing capability of at least one piece of testing equipment 106. Each piece of testing equipment 106 may be associated with a single testing capability in a single row 502 or with multiple testing capabilities in multiple rows 502. Note that this organization is used merely for convenience, and the testing capabilities 500 may be stored or expressed in any other suitable manner.

Each row 502 of the table includes an equipment identification number 504, which identifies the test equipment 106 associated with the testing capability contained in that row 502. In this example, multiple rows 502 are associated with the same equipment identification number 504 to indicate that the same test equipment 106 has different capabilities. However, each piece of test equipment 106 may be associated with any number of rows 502. Also, in this example, the equipment identification numbers 504 are expressed using alphanumeric characters, although any other suitable identifiers may be used here.

Each row 502 of the table also includes object text 506, which may represent text obtained from the testing capabilities information 122. Each object text 506 expresses at least part of a testing capability for at least one piece of testing equipment 106. For example, an object text 506 can identify a specific type of input that can be provided to a hardware product to be tested or a specific type of output that can be measured from a hardware product to be tested. In some cases, each object text 506 represents text from the testing capabilities information 122 that has been identified (by the natural language processing operation 302b based on at least one NLP model 124) as containing at least one testing capability.

Each row 502 of the table further includes a classification 508 and a type 510, which represent derived capability characteristics obtained from the object text 506 in the row 502. For instance, the classification 508 can indicate whether the row 502 is associated with a stimulus or measurement capability characteristic, and the type 510 can indicate the specific type of stimulus that can be provided or the specific type of measurement that can be captured. In addition, each row 502 of the table includes a lower specification limit (LSL) 512, an LSL unit of measure 514, an upper specification limit (USL) 516, and a USL unit of measure 518. The lower specification limit 512 and the upper specification limit 516 provide a range of values that can be provided as a stimulus or captured in a measurement by the associated test equipment 106, and the units of measure 514 and 518 respectively provide the units in which the lower specification limit 512 and the upper specification limit 516 are expressed. The entries 508-518 in the table of FIG. 5 can be produced by the natural language processing operation 302b analyzing the input texts (the object texts 506) using one or more appropriately-trained NLP models 124.

The tables shown in FIGS. 4 and 5 illustrate the types of information that may be obtained, processed, and generated by the functional architecture 300 in order to support automated gap analysis. For example, at least some of the information from the table in FIG. 5 may be used by the processing device 202 to identify the overall testing capabilities of all of the testing equipment 106, such as by generating at least one ontology 126 that contains or represents these testing capabilities. At least some of the information from the table in FIG. 4 may be compared by the processing device 202 to the known testing capabilities of the testing equipment 106 in order to identify any gaps between the testing requirements information 120 and the testing capabilities information 122. As a particular example, if nothing in the table of FIG. 5 indicates that testing equipment 106 has the ability to generate a radio frequency (RF) signal with a reference frequency of 5 GHz±5 kHz, the functional architecture 300 can identify a gap related to the “RF Signal Input” row of the table in FIG. 4. Since this can occur using only the testing requirements information 120 and the testing capabilities information 122, this enables concurrent engineering and integrated development of both hardware requirements and testing requirements.

Although FIG. 4 illustrates one example of testing requirements 400 for a hardware product and FIG. 5 illustrates one example of testing capabilities 500 for testing equipment 106 used to support integrated requirements development and automated gap analysis, various changes may be made to FIGS. 4 and 5. For example, the contents of the tables shown in FIGS. 4 and 5 are merely meant to illustrate the types of information that may be received or generated by the functional architecture 300. The functional architecture 300 need not actually generate tables containing the specific information shown in FIGS. 4 and 5.

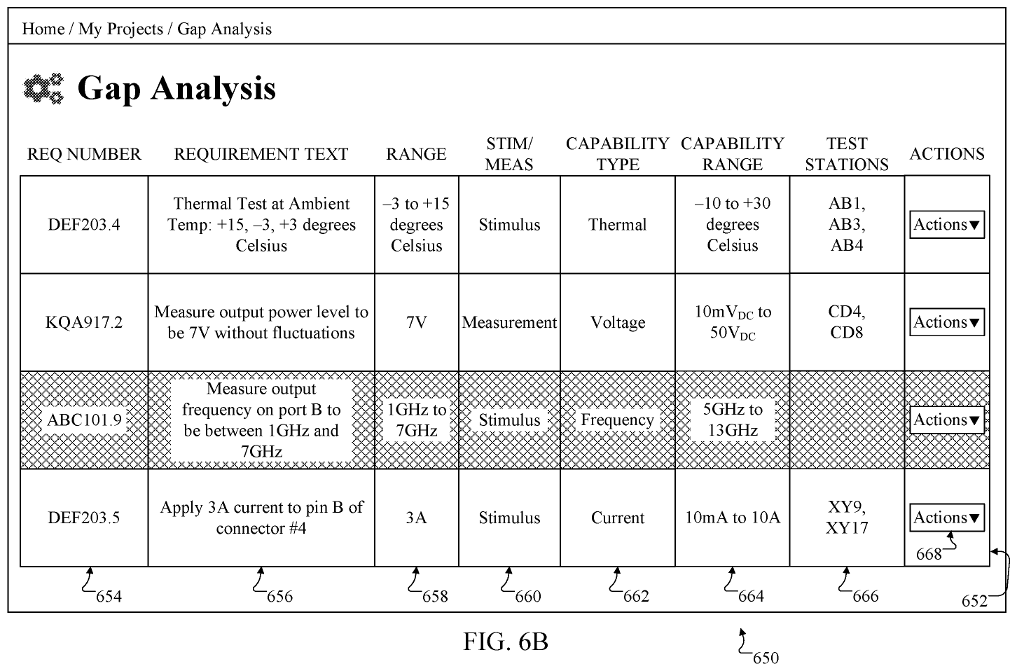

FIGS. 6A and 6B illustrate example graphical user interfaces 600 and 650 supporting integrated requirements development and automated gap analysis for hardware testing using natural language processing according to this disclosure. For ease of explanation, the graphical user interfaces 600 and 650 shown in FIGS. 6A and 6B may be described as being generated by the graphical user interface operation 306 in the functional architecture 300 of FIG. 3, which may be implemented or supported using one or more components in the system 100 of FIG. 1 (at least one of which may be implemented using at least one instance of the device 200 of FIG. 2). However, the graphical user interfaces 600 and 650 shown in FIGS. 6A and 6B may be generated in any suitable functional architecture that is implemented or supported by any suitable device(s) and in any suitable system(s).

As shown in FIG. 6A, the graphical user interface 600 may be used by a user to provide one or more testing requirements to the analysis operation 304. The one or more testing requirements provided via the graphical user interface 600 may be used to supplement or replace one or more testing requirements contained in the testing requirements information 120. In some cases, it may also be possible for the testing requirements provided via the graphical user interface 600 to represent all of the testing requirements information 120 processed by the analysis operation 304.

The graphical user interface 600 here includes a text box 602, which allows a user to manually create or modify a testing requirement. For example, a user may manually type a new testing requirement into the text box 602, where the new testing requirement is expressed as a manually-defined stimulus and/or measurement. A user may also retrieve a previously-defined testing requirement into the text box 602 and edit the previously-defined testing requirement. Information 604 can be presented related to the testing requirement in the text box 602, such as when the testing requirement was created and (if applicable) last edited or updated. Buttons 606 can be used to invoke specific functions related to the testing requirement in the text box 602. For instance, a “synonyms” button 606 can be selected to view other words that might be used in place of the words currently in the text box 602.

If the user selects an “analyze” button 606, at least one NLP model 124 can be applied to the testing requirement contained in the text box 602, and a results box 608 presents the testing requirement from the text box 602 as analyzed by the NLP model(s) 124. For example, the results box 608 can present the same testing requirement as in the text box 602, but different portions of the testing requirement in the results box 608 can have different associated indicators 610. The indicators 610 represent how the applied NLP model(s) 124 analyzed different portions of the testing requirement from the text box 602. For instance, the indicators 610 may be used to identify different portions of the testing requirement as being related to a stimulus or measurement, a target value or upper/lower bounds, and units of measure. In this example, the indicators 610 are represented as different line patterns, although other types of indicators (such as highlighting in different colors) may be used. Also, in this example, three specific values (+15° C., +3° C., and −3° C.) are included in the text, but only two values (+15° C. and −3° C.) are underlined, indicating the model 124 has identified the upper and lower bounds of the range of the test requirement.

In some cases, a user may select a specific portion of the testing requirement in the results box 608, such as by hovering over a word or phrase of the testing requirement in the results box 608 using a mouse. Information about that particular portion of the testing requirement may then be presented in the graphical user interface 600, such as information showing how that particular portion of the testing requirement was analyzed by the applied NLP model(s) 124.

A classification 612 can also be included in the graphical user interface 600 and may identify (based on the analysis of the testing requirement) whether the testing requirement in the text box 602 appears to be a stimulus, a measurement, or possibly both. In this example, the testing requirement in the text box 602 defines a stimulus, namely the application of different ambient temperatures. The classification 612 here correctly identifies the testing requirement as being a stimulus.

Collectively, the box 608 and the classification 612 may allow a user to review how the testing requirement in the text box 602 would be analyzed by at least one NLP model 124 as part of the natural language processing operation 302a. This allows the user to determine whether the testing requirement in the text box 602 is achieving the desired result in terms of being analyzed by the NLP model(s) 124 and the natural language processing operation 302a.

Although not shown here, a similar type of graphical user interface may be provided so that one or more users can provide at least one testing capability for at least one piece of testing equipment 106 to the analysis operation 304. The one or more testing capabilities provided via such a graphical user interface may be used to supplement or replace one or more testing capabilities contained in the testing capabilities information 122. In some cases, it may also be possible for the testing capabilities provided via the graphical user interface to represent all of the testing capabilities information 122 processed by the analysis operation 304.

As shown in FIG. 6B, the graphical user interface 650 may be used to provide one or more analysis results from the analysis operation 304 to a user. The one or more analysis results provided via the graphical user interface 650 can include any identified gaps between the desired testing of a hardware product (as defined by the testing requirements information 120) and actual testing capabilities of the testing equipment 106 (as defined by the testing capabilities information 122).

The graphical user interface 650 here includes a table with various rows 652, where each row 652 of the table is associated with at least part of a different testing requirement. Each testing requirement identified from the testing requirements information 120 may be associated with a single row 652 or multiple rows 652 in the analysis results. Note that this organization is used merely for convenience, and the analysis results may be stored or expressed in any other suitable manner.

Each row 652 of the table includes a requirement number 654, which identifies the testing requirement contained in or otherwise associated with that row 652. Each row 652 of the table also includes requirement text 656, which may represent text obtained from the testing requirements information 120 for the associated testing requirement. The requirement numbers 654 are expressed using alphanumeric characters, although any other suitable identifiers may be used here. Each requirement text 656 expresses at least part of a hardware test associated with a hardware product to be tested, such as the application of at least one stimulus to a hardware product and/or the capture of at least one measurement from the hardware product. The requirement numbers 654 here may be based on the product requirement numbers 404 identified previously, and the requirement texts 656 here may be based on the product requirement texts 406 identified previously. In some embodiments, the requirement numbers 654 may include or represent hyperlinks that can be selected by users to view the associated test requirements, such as the associated portion of the testing requirements information 120. Each row 652 of the table also includes a range 658 and a category 660, which respectively identify the input or output range associated with the test requirement in the row 652 and whether the test requirement in the row 652 is a stimulus or measurement. The ranges 658 and categories 660 here may be based on the derived test requirements 408 and/or tolerances 410 identified previously.

Each row 652 of the table further includes a capability type 662, a capability range 664, and one or more optional test station identifiers 666. The capability type 662 identifies a type of stimulus or measurement that at least one piece of test equipment 106 can achieve to satisfy the test requirement in the row 652, and the capability range 664 identifies the range of stimulus or measurement values that can be achieved by at least one piece of test equipment 106 to satisfy the test requirement in the row 652. If the test requirement in the row 652 can be satisfied by at least one piece of test equipment 106, the one or more test station identifiers 666 identify the at least one piece of test equipment 106 that can satisfy that test requirement. The capability types 662 and capability ranges 664 here may be based on the types 510, lower specification limits 512, upper specification limits 516, and units of measure 514 and 518 identified previously. The test station identifiers 666 are expressed using alphanumeric characters, although any other suitable identifiers may be used here. The test station identifiers 666 here may be based on the equipment identification numbers 504 identified previously.

In addition, each row 652 includes an “actions” button 668, which can be used by a user to invoke various actions in relation to the test requirement in the row 652. For example, the actions may include re-running the analysis performed by the functional architecture 300, such as to account for any changes made to the testing requirements information 120 and/or the testing capabilities information 122. The actions may also include editing the testing requirement or its details, such as to account for improper classifications or other analyses made by the NLP models 124. The actions may further include correcting one or more NLP models 124, such as when a subject matter expert can provide correction data that alters one or more NLP models 124. In addition, the actions may include deleting the specific testing requirement.

One or more indicators can be used in the table shown in FIG. 6B to identify any gaps between the desired testing of a hardware product and the actual testing capabilities of the testing equipment 106. For example, different rows 652 of the table may be highlighted in different colors, such as when rows 652 associated with achievable testing requirements are highlighted in green and rows 652 associated with unachievable testing requirements are highlighted in red. In this particular example, a single row 652 of the table is highlighted, which is done merely for convenience of illustration. The highlighted row 652 in FIG. 6B represents a testing requirement that cannot be achieved, in this example because the frequency range of a desired test (1 GHz to 7 GHz) is outside the capability range (5 GHz to 13 GHz) for available testing equipment 106. Of course, this is merely for illustration, and any number of rows 652 (or no rows 652) may be highlighted or otherwise identified depending on the number of gaps (if any) located during the analysis. Note that the inclusion of various information in the graphical user interface 650, such as the ranges 658 and 664, can help users to quickly identify why various capability gaps exist between the testing requirements and the capabilities of the testing equipment 106.

Although FIGS. 6A and 6B illustrate examples of graphical user interfaces 600 and 650 supporting integrated requirements development and automated gap analysis for hardware testing using natural language processing, various changes may be made to FIGS. 6A and 6B. For example, the graphical user interface 600 may not be needed if users are not permitted to manually create or edit testing requirements separate from the testing requirements information 120. Also, the contents, layouts, and arrangements of the graphical user interfaces 600 and 650 shown here are for illustration only. Each graphical user interface 600 and 650 may include any suitable information that is presented in any suitable manner within the graphical user interfaces 600 and 650. In addition, information may be collected from or provided to users in any other suitable manner.

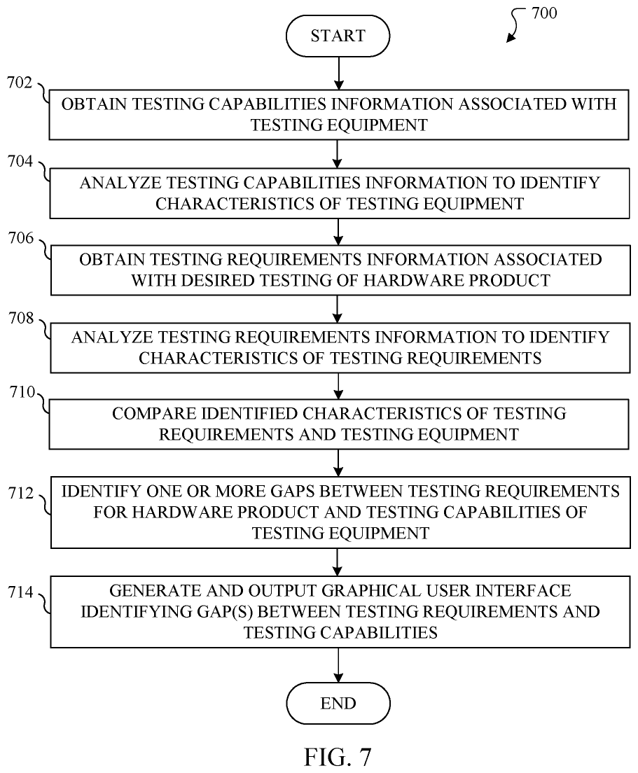

FIG. 7 illustrates an example method 700 for integrated requirements development and automated gap analysis for hardware testing using natural language processing according to this disclosure. For ease of explanation, the method 700 shown in FIG. 7 may be described as involving the use of the functional architecture 300 of FIG. 3, which may be implemented or supported using one or more components in the system 100 of FIG. 1 (at least one of which may be implemented using at least one instance of the device 200 of FIG. 2). However, the method 700 shown in FIG. 7 may be used in any suitable functional architecture that is implemented or supported by any suitable device(s) and in any suitable system(s).

As shown in FIG. 7, testing capabilities information associated with testing equipment is obtained at step 702. This may include, for example, the processing device 202 of the application server 112 or other device 200 obtaining testing capabilities information 122 associated with the testing equipment 106. The testing capabilities information 122 identifies various capabilities of the testing equipment 106, such as current or anticipated capabilities of the testing equipment 106. In some embodiments, at least one of the testing capabilities of the testing equipment 106 may be provided by a user via a graphical user interface, such as a graphical user interface similar to the graphical user interface 600 shown in FIG. 6A.

The testing capabilities information is analyzed to identify specific characteristics of the testing equipment at step 704. This may include, for example, the processing device 202 of the application server 112 or other device 200 performing the natural language processing operation 302b using one or more NLP models 124 that have been trained to extract the specific characteristics of the testing equipment 106 from the testing capabilities information 122. In some embodiments, this may include the processing device 202 of the application server 112 or other device 200 generating one or more ontologies 126 that capture or express the specific characteristics of the testing equipment 106.

Testing requirements information associated with desired testing of a hardware product is obtained at step 706. This may include, for example, the processing device 202 of the application server 112 or other device 200 obtaining testing requirements information 120 associated with a hardware product being designed. The testing requirements information 120 identifies various requirements for desired testing of the hardware product being designed. In some embodiments, at least one of the testing requirements of the hardware product may be provided by a user via a graphical user interface, such as the graphical user interface 600 shown in FIG. 6A.

The testing requirements information is analyzed to identify specific characteristics of the testing requirements at step 708. This may include, for example, the processing device 202 of the application server 112 or other device 200 performing the natural language processing operation 302a using one or more NLP models 124 that have been trained to extract the specific characteristics of the testing requirements from the testing requirements information 120.

The identified characteristics of the testing requirements for the hardware product are compared to the identified characteristics of the capabilities of the testing equipment at step 710. This may include, for example, the processing device 202 of the application server 112 or other device 200 performing the analysis operation 304 to compare the identified characteristics of the testing requirements to the one or more ontologies 126 or otherwise determining whether all identified characteristics of the testing requirements can be satisfied by the identified characteristics of the capabilities of the testing equipment 106. If present, one or more gaps between the testing requirements for the hardware product and the testing capabilities of the testing equipment are identified at step 712. This may include, for example, the processing device 202 of the application server 112 or other device 200 determining which identified characteristics of the testing requirements cannot be satisfied by the identified characteristics of the capabilities of the testing equipment 106.

A graphical user interface identifying the one or more gaps between the testing requirements for the hardware product and the testing capabilities of the testing equipment is generated and presented at step 714. This may include, for example, the processing device 202 of the application server 112 or other device 200 performing the graphical user interface operation 306 to present the one or more identified gaps (or information associated with the one or more identified gaps) to a user via a graphical user interface, such as the graphical user interface 650 shown in FIG. 6B. The graphical user interface 650 may contain any additional information as needed or desired.

Although FIG. 7 illustrates one example of a method 700 for integrated requirements development and automated gap analysis for hardware testing using natural language processing, various changes may be made to FIG. 7. For example, while shown as a series of steps, various steps in FIG. 7 may overlap, occur in parallel, occur in a different order, or occur any number of times.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive (HDD), a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable storage device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present application should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A method comprising:
analyzing testing capabilities information associated with multiple pieces of testing equipment by performing a first natural language processing (NLP) operation to identify capabilities of the testing equipment during hardware testing;
analyzing testing requirements information associated with a design of a hardware device by performing a second NLP operation to identify characteristics of testing requirements to be used to test the hardware device;
identifying at least one gap between the testing requirements to be used to test the hardware device and the capabilities of the testing equipment; and
generating a graphical user interface identifying the at least one gap.

2. The method of claim 1, wherein each of the first and second NLP operations uses at least one trained NLP model.

3. The method of claim 2, wherein the first and second NLP operations use different trained NLP models.

4. The method of claim 1, wherein:
analyzing the testing capabilities information comprises generating at least one ontology that captures the capabilities of the testing equipment; and
identifying the at least one gap comprises comparing the characteristics of the testing requirements to be used to test the hardware device against the at least one ontology.

5. The method of claim 1, wherein:
analyzing the testing capabilities information to identify the capabilities of the testing equipment comprises identifying, for each capability of the testing equipment, at least one of:
a first category indicating whether the capability relates to a stimulus or a measurement;
a type of the stimulus or measurement for the capability;
upper and lower bounds for the capability; and
a unit of measure for the capability; and
analyzing the testing requirements information to identify the characteristics of the testing requirements comprises identifying, for each testing requirement, at least one of:
a second category indicating whether the testing requirement relates to a stimulus or a measurement;
a type of the stimulus or measurement for the testing requirement;
a target value for the testing requirement;
acceptable upper and lower bounds for the testing requirement; and
a unit of measure for the testing requirement.

6. The method of claim 1, wherein at least one of the capabilities of the testing equipment or at least one of the testing requirements is obtained from a user.

7. The method of claim 6, further comprising:
applying at least one trained natural language processing (NLP) model to the at least one capability or the at least one testing requirement obtained from the user; and
displaying to the user how the at least one trained NLP model analyzes the at least one capability or the at least one testing requirement obtained from the user.

8. An apparatus comprising:
at least one memory configured to store:
testing capabilities information associated with multiple pieces of testing equipment; and
testing requirements information associated with a design of a hardware device; and
at least one processor configured to:
analyze the testing capabilities information by performing a first natural language processing (NLP) operation to identify capabilities of the testing equipment during hardware testing;
analyze the testing requirements information by performing a second NLP operation to identify characteristics of testing requirements to be used to test the hardware device;
identify at least one gap between the testing requirements to be used to test the hardware device and the capabilities of the testing equipment; and
generate a graphical user interface identifying the at least one gap.

9. The apparatus of claim 8, wherein, to perform each of the first and second NLP operations, the at least one processor is configured to use at least one trained NLP model.

10. The apparatus of claim 9, wherein, to perform the first and second NLP operations, the at least one processor is configured to use different trained NLP models.

11. The apparatus of claim 8, wherein:
the at least one processor is configured to generate at least one ontology that captures the capabilities of the testing equipment; and
to identify the at least one gap, the at least one processor is configured to compare the characteristics of the testing requirements to be used to test the hardware device against the at least one ontology.

12. The apparatus of claim 8, wherein:
to analyze the testing capabilities information to identify the capabilities of the testing equipment, the at least one processor is configured to identify, for each capability of the testing equipment, at least one of:
a first category indicating whether the capability relates to a stimulus or a measurement;
a type of the stimulus or measurement for the capability;
upper and lower bounds for the capability; and
a unit of measure for the capability; and
to analyze the testing requirements information to identify the characteristics of the testing requirements, the at least one processor is configured to identify, for each testing requirement, at least one of:
a second category indicating whether the testing requirement relates to a stimulus or a measurement;
a type of the stimulus or measurement for the testing requirement;
a target value for the testing requirement;
acceptable upper and lower bounds for the testing requirement; and
a unit of measure for the testing requirement.

13. The apparatus of claim 8, wherein the at least one processor is configured to obtain at least one of the capabilities of the testing equipment or at least one of the testing requirements from a user.

14. The apparatus of claim 13, wherein the at least one processor is further configured to:
apply at least one trained natural language processing (NLP) model to the at least one capability or the at least one testing requirement obtained from the user; and
present to the user how the at least one trained NLP model analyzes the at least one capability or the at least one testing requirement obtained from the user.

15. A non-transitory computer readable medium containing instructions that when executed cause at least one processor to:
analyze testing capabilities information associated with multiple pieces of testing equipment by performing a first natural language processing (NLP) operation to identify capabilities of the testing equipment during hardware testing;
analyze testing requirements information associated with a design of a hardware device by performing a second NLP operation to identify characteristics of testing requirements to be used to test the hardware device;
identify at least one gap between the testing requirements to be used to test the hardware device and the capabilities of the testing equipment; and
generate a graphical user interface identifying the at least one gap.

16. The non-transitory computer readable medium of claim 15, wherein the first and second NLP operations are configured to use different trained NLP models.

17. The non-transitory computer readable medium of claim 15, wherein:
the instructions that when executed cause the at least one processor to analyze the testing capabilities information to identify the capabilities of the testing equipment comprise:
instructions that when executed cause the at least one processor to generate at least one ontology that captures the capabilities of the testing equipment; and
the instructions that when executed cause the at least one processor to identify the at least one gap comprise:
instructions that when executed cause the at least one processor to compare the characteristics of the testing requirements to be used to test the hardware device against the at least one ontology.

18. The non-transitory computer readable medium of claim 15, wherein:
the instructions that when executed cause the at least one processor to analyze the testing capabilities information to identify the capabilities of the testing equipment comprise:
instructions that when executed cause the at least one processor to identify, for each capability of the testing equipment, at least one of:
a first category indicating whether the capability relates to a stimulus or a measurement;
a type of the stimulus or measurement for the capability;
upper and lower bounds for the capability; and
a unit of measure for the capability; and
the instructions that when executed cause the at least one processor to analyze the testing requirements information to identify the characteristics of the testing requirements comprise:
instructions that when executed cause the at least one processor to identify, for each testing requirement, at least one of:
a second category indicating whether the testing requirement relates to a stimulus or a measurement;
a type of the stimulus or measurement for the testing requirement;
a target value for the testing requirement;
acceptable upper and lower bounds for the testing requirement; and
a unit of measure for the testing requirement.

19. The non-transitory computer readable medium of claim 15, further containing instructions that when executed cause the at least one processor to obtain at least one of the capabilities of the testing equipment or at least one of the testing requirements from a user.

20. The non-transitory computer readable medium of claim 19, further containing instructions that when executed cause the at least one processor to:
apply at least one trained natural language processing (NLP) model to the at least one capability or the at least one testing requirement obtained from the user; and
present to the user how the at least one trained NLP model analyzes the at least one capability or the at least one testing requirement obtained from the user.
